(19) United States
(12) Patent Application Publication
(10) Pub. No.: US 2014/0326495 A1
(43) Pub. Date: Nov. 6, 2014

(54) HIGH PERFORMANCE PRINTED CIRCUIT BOARD

(71) Applicant: Jose Ricardo Paniagua, Newmarket, NH (US)

(72) Inventor: Jose Ricardo Paniagua, Newmarket, NH (US)

(73) Assignee: Amphenol Corporation, Wallingford Center, CT (US)

(21) Appl. No.: 14/240,960

(22) PCT Filed: Aug. 27, 2012
(86) PCT No.: PCT/US2012/052503

§ 371 Date: Jul. 25, 2014

Related U.S. Application Data
(60) Provisional application No. 61/527,565, filed on Aug. 25, 2011.

(51) Int. Cl. H05K 1/11; H05K 3/42; H05K 3/10; H05K 3/00

(52) U.S. Cl. CPC H05K 1/116; H05K 3/0005; H05K 3/42; H05K 3/10; H05K 2201/0784; H05K 2201/09372; H05K 2201/095
USPC 174/266; 716/137; 29/852

(57) ABSTRACT

A printed circuit board for carrying high frequency signals. Conducting structures of the printed circuit board are shaped within breakout regions to limit impedance discontinuities in the signal paths between vias and conductive traces within the printed circuit board. Values of parameters of traces or anti-pads, for example, may be adjusted to provide a desired impedance. The specific values selected as part of designing a printed circuit board may match the impedance of the breakout region to that of the via. The parameters for which values are selected may include the trace width, thickness, spacing, length over an anti-pad or angle of exit from the breakout region.

### BACKGROUND

Printed circuit boards are frequently used in manufacturing electronic systems. Components, such as integrated circuit chips and connectors, are attached to the boards. The printed circuit boards provide a mechanism to connect leads of these components.

A conventional approach to manufacturing printed circuit boards is to stack up sheets of insulative material on which metal has been deposited. For some of the sheets, the metal is patterned to form conductive traces, which act as wires that carry electrical signals or potentials. The sheets are then fused to form a solid substrate to which the components can be mounted. Other than metal formed on the outermost sheet, the metal is inside the substrate.

The traces, because they are formed as part of the sheets, run in planes parallel to the surface of the board. To make connections between traces in different planes or to make connections between traces interior to the board and components on the surface of the board, holes may be drilled partially or fully through the board, passing through portions of the traces. The interior of these holes are then be plated with more metal, which forms conducting “vias” between all of the traces on different layers through which the vias pass.

Various approaches are known to make connections between components and the vias. In surface mount manufacturing techniques, a conducting pad may be formed around a via, and a lead of a component may be soldered to the pad. In other attachment techniques, a portion of a lead may be inserted into the via. For some technologies, the lead may be soldered to the via. For press fit technologies, the portion of the lead may be compliant such that it is compressed as it is inserted into the via. Once inserted into the via, the compliant portion presses against the side of the walls of the via, making both an electrical and a mechanical connection between the lead of the component and the via.

Any suitable type of components may be mounted to the printed circuit board using these techniques. Though, designing a printed circuit board for attachment of an electrical connector can be particularly challenging. An electrical connector frequently has numerous conducting elements carrying signals in a relatively small area. As a result, many traces must run near each other in the area where the connector is attached to the printed circuit board, sometimes described as the connector “foot print.” In addition, many vias must exist in the connector footprint to enable connections between those traces and the conductors in the connector. These vias limit the areas in which traces can be run. Though, it is known to position the vias to leave space between columns or rows of vias. These spaces serve as “routing channels” for traces carrying signals to or from the vias connected to leads of the connector. To complete a connection between a via, which is in turn coupled to a lead of the connector, and a trace in a routing channel, a “breakout region” may be included. The breakout region includes a portion of the trace designed to connect to a corresponding via.

Various techniques are used in manufacturing printed circuit boards for high frequency signals. In some instances, to improve high frequency performance, signal carrying conducting elements, such as traces and vias, are routed in pairs, called “differential pairs.” Each differential pair carries one signal in a form called a “differential signal” in which the difference in voltage level between the conducting elements of the pair constitutes the signal. Differential signals are less susceptible to noise, which can interfere with reliable propagation of high speed signals through an interconnection system, than single-ended signals.

Another technique that improves high frequency performance is the incorporation of ground planes in the printed circuit board. A ground plane can be formed from the metal layer on a sheet of insulative material used to form the printed circuit board. Rather than forming a pattern of traces in that metal, substantially all of the metal may be left on a sheet. Some openings may be formed in the metal layer around vias that are not intended to be connected to the metal layer. However, these openings, sometimes called “anti-pads” or described as providing a ground clearance, still allow the metal layer, when connected to a voltage that operates as a reference potential to a high speed signal, to act as a large, planar ground.

The ground plane can shield traces on different layers of the printed circuit board, blocking signals propagating along traces on one layer from interfering with signals propagating along traces on a different layer. Additionally, the ground plane may be used to control the impedance of the traces to provide an impedance that matches an impedance with which circuits mounted to the board are intended to operate. This impedance control is achieved by controlling, among other parameters of the printed circuit board design, the spacing between signal traces and the ground planes. Accordingly, a high speed printed circuit board may have a ground plane between every layer of signal traces.

Back drilling is another approach that is used in high frequency printed circuit boards. Back drilling removes unnecessary portions of vias that can interfere with the propagation of high frequency signals. These unnecessary portions result from vias formed by drilling holes through a printed circuit board and then plating the inside of the hole. The plating is only needed on the portion of the via that runs between the layers of the printed circuit board to be connected by the via. The remainder of the plating can interfere with high frequency operation. By drilling partially through the thickness of the printed circuit board to enlarge the plated via, this additional plating is removed, thereby increasing high frequency performance.

### SUMMARY

An improved high frequency printed circuit board design is provided through the design of “breakout regions.” The breakout regions are configured to provide an impedance that avoids multiple impedance discontinuities in signal paths between vias and signal traces of the printed circuit board. One or more parameters of the breakout regions may be selected to limit the number of impedance discontinuities created.

Accordingly, in some aspects, the invention may relate to a method of designing a printed circuit board. As part of the method, values of parameters of the breakout region may be selected to provide a desired impedance profile across the breakout region.

In another aspect, the invention may relate to a method of manufacturing a printed circuit board. The method may entail selecting values of parameters defining the breakout region and then forming a design file capturing the parameters. The values may be selected to reduce a number of impedance discontinuities in signal paths through the breakout regions. The design file may be subsequently used to create masks or other patterning mechanism used in the manufacture of printed circuit boards including the selected parameter values.

In another aspect, the invention may relate to a tool for designing a printed circuit board. The tool may comprise computer-executable instructions encoded on a computer-readable storage medium that, when executed, control at least one processor to perform a method of determining values of one or more parameters of one or more breakout regions on a printed circuit board. The values may be selected to provide a desired impedance profile for providing improved high frequency performance. The values, for example, may be selected to provide a single impedance discontinuity across the breakout region. Such an impedance profile may be achieved by selecting values of parameters that provide traces within the breakout region that match the impedance of the via. In some embodiments, the method performed by the tool may include computing an impedance of a via associated with a breakout region and then selecting values of one or more design parameters of a breakout region based on that computed impedance.

In yet a further aspect, the invention may relate to a printed circuit board having breakout regions configured for high frequency performance. The breakout region may have structures with an impedance that provides a limited number of impedance discontinuities between vias and traces within the printed circuit board. Such structures may have values of design parameters that provide the desired impedance to each breakout region.

In some embodiments, the structures in the breakout regions may be adapted and configured to provide an impedance that is consistent with the impedance of corresponding vias. Providing consistent impedances may avoid discontinuities. In scenarios in which different vias have different impedances, different values of the design parameters may be used in different breakout regions. As a result, different breakout regions on a printed circuit board—possibly even within the same component footprint—may have different values for corresponding design parameters. In some embodiments, adjacent breakout regions in the same connector footprint may have different values of design parameters. As a specific example, breakout regions corresponding to vias that have been back drilled may have different parameter values than breakout regions corresponding to vias that have not been back drilled.

In some embodiments, parameters may be selected to provide an impedance through the breakout regions that is consistent with the impedance of the vias. Such an impedance may be achieved with an impedance in the breakout region that is more closely matched to the via than to the trace outside the breakout region. For example, the impedance of the via may be more than ten percent (10%) less than the impedance of traces outside the breakout region. The traces within the breakout region may have an impedance that is within 7% of the impedance of the via. As a specific example, traces outside the breakout region may have a nominal impedance of 85 Ohms. Vias may have a nominal impedance of 70 Ohms. The traces within the breakout region may have an impedance of 75 Ohms or less.

In some embodiments, high speed signals may be carried on differential pairs of traces and vias. In such scenarios, the impedances that are selected to be consistent may be differential impedances.

Also, in some embodiments, the parameters for which values are selected may include the width of the traces within the breakout region, an angle of the traces relative to an anti-pad, a length of trace passing over an anti-pad, the size of the anti-pad, a spacing between traces that form a differential pair and/or a thickness of the trace.

The foregoing is a non-limiting summary of the invention.

### BRIEF DESCRIPTION OF DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1 is a sketch, partially exploded, of a portion of a component footprint in a printed circuit board;

FIG. 2A is a schematic cross-sectional illustration of a breakout region of a printed circuit board;

FIG. 2B is a schematic cross-sectional illustration of a breakout region of a printed circuit board in which signal vias have been back drilled;

FIG. 2C is a schematic plan view of a breakout region of a printed circuit board;

FIGS. 3A, 3B and 3C are schematic plan views of breakout regions of a printed circuit board;

FIG. 3D is an enlarged view of traces exiting vias, illustrating parameters that may be varied to configure a breakout region with a desired impedance;

FIG. 4 is a schematic plan view of a breakout region, illustrating variation of a width of a ground clearance to control an impedance profile in a breakout region;

FIG. 5 is a schematic plan view of a breakout region of a printed circuit board in which a value of a trace spacing parameter is selected to control impedance in a breakout region of the printed circuit board;

FIG. 6 is a schematic plan view of multiple breakout regions in a component footprint of a portion of a printed circuit board;

FIGS. 7A and 7B are plots illustrating insertion loss profiles of the breakout regions illustrated in FIG. 6;

FIGS. 8A and 8B are TDR plots of signals passed through the breakout regions illustrated in FIG. 6;

FIGS. 9A and 9B are insertion loss profiles of breakout regions as illustrated in FIG. 6 in an alternative embodiment in which the vias of the breakout regions have been back drilled;

FIGS. 10A and 10B are TDR plots of signals propagating through the breakout regions as illustrated in FIG. 6 in an alternative embodiment in which the vias of the breakout regions have been back drilled;

FIGS. 11A and 11B are plots of insertion loss profiles of breakout regions as illustrated in FIG. 6 according to a further alternative embodiment;

FIGS. 12A and 12B are TDR plots of signals propagating through breakout regions as illustrated in FIG. 6 according to the alternative embodiment illustrated in FIGS. 11A and 11B;

FIGS. 13A and 13B are insertion loss profiles of breakout regions as illustrated in FIG. 6 according to a further alternative embodiment in which a width of an antipad of each breakout region has been varied;

FIGS. 14A and 14B are TDR plots of signals propagating through the breakout regions implemented according to the embodiment of FIGS. 13A and 13B; and

FIG. 15 is a schematic illustration of a computing system that may be adapted to generate a data file specifying a printed circuit board including breakout regions in which the impedance has been configured for improved high frequency performance.

### DETAILED DESCRIPTION

The inventor has recognized and appreciated that improved high frequency performance of a printed circuit board may be achieved by controlling the impedance of breakout regions within a footprint for a connector or other component to be mounted to a printed circuit board. The impedance may be controlled to reduce the number of impedance transitions in the signal paths that carry high speed signals through the printed circuit board. The inventor has recognized and appreciated that, though the breakout region may be a relatively small portion of the overall signal path through a via and along traces of the printed circuit board, impedance characteristics in the breakout region can have a significant impact on the integrity of signals propagating along that path.

Further, the inventor has recognized and appreciated that, at high frequencies, such as those associated with signals with data rates above 3 Gigabits per second (Gbps), patterns of changes in impedance can be significant. The pattern of impedance change in the breakout region may impact the “flatness” of the insertion loss profile as a function of frequency. The flatness of the insertion loss profile may in turn dictate the maximum frequency component of signals that can reliably pass along the signal path, thus limiting the data rate of signals that can pass along the signal path.

In embodiments in which the breakout region is part of a connector footprint in an interconnection system within an electronic assembly, insertion loss within the breakout region may be additive with insertion loss in other portions of the interconnection system. By limiting the insertion loss in the breakout region, the interconnection system can carry higher frequency signals, which may allow the electronic system to operate at higher data rates.

In some embodiments, providing a pattern of impedance change with a limited number of impedance discontinuities in the breakout region contributes to a more flat insertion loss profile. Reducing a number of impedance discontinuities in the breakout region may provide an improvement relative to designs in which the overall change in impedance between the via and a trace running within the printed circuit board is the same, but with more discontinuities. In some embodiments, a flat insertion loss profile is achieved by selecting values of design parameters in the breakout region to limit the number of impedance discontinuities. This result may be achieved, for portions of the breakout region, by selecting parameters for each of one or more portions of the signal path that result in an impedance that is consistent with an impedance of an adjacent portion.

In some embodiments, portions of the breakout region may be designed such that all or significant portions of the breakout region have an impedance consistent with the impedance of the via or the trace. Such an impedance profile may have a single impedance discontinuity in the signal path between the via and the traces running within the printed circuit board. In a presently preferred embodiment, the impedance of the breakout region is matched to the impedance of the via.

Though the breakout region may be a relatively small portion of the overall signal path, the inventor has recognized and appreciated that for high frequency signals, such as signals in excess of 6 Gbps, controlling the impedance profile reduces discontinuities, which can be a significant source of signal degradation. Accordingly, a high performance printed circuit board may be designed using techniques as described herein for carrying signals in excess of 6 Gbps. In some case, these printed circuit boards may be used in systems carrying signals at data rates in excess of 8 Gbps, 10 Gbps or in other embodiments in excess of 14 Gbps. In some embodiments, these techniques may be used at data rates up to 20 Gbps (or at any data rate less than that). Though, it should be appreciated that the specific data rates enabled by these techniques is not critical to the invention, as improvements in signal integrity may be obtained at many frequencies, including frequencies associated with data rates greater than 20 Gbps.

Any of a number of parameters of the design of the breakout region may be varied to provide a desired impedance profile across the breakout region. In some embodiments, values of parameters of the traces in the breakout region are different for portions of the breakout region overlying a ground plane versus a ground clearance. Values of these parameters may be selected to provide a consistent impedance for both portions of the trace in the breakout region. For example, the width of the trace may be different over a ground clearance than over a ground plane so as to avoid an impedance discontinuity at the interface between the ground clearance to the ground plane.

Though, values of any suitable parameters may be selected to provide a desired impedance profile. The following description provides examples of parameters for which values may be varied to provide a desired impedance. It should be appreciated that embodiments may be formed in which values for one or more of these parameters are selected in a single breakout region. Moreover, it should be appreciated that different values of these parameters could be provided for different breakout regions within the same electronic assembly, or possibly on the same printed circuit board, or possibly within the same component footprint. For example, in scenarios in which single-ended and differential signals are mixed, selecting values of parameters that reduce the number of impedance discontinuities across the breakout regions may result in different values of the same parameters for breakout regions associated with single ended versus differential signals. Though, even for breakout regions associated with the same signal format, different values of the same parameters may be selected for breakout regions associated with vias that connect to different layers within the printed circuit board. As another example, different values of the same parameters may be selected for breakout regions associated with vias that are back drilled versus those that are not.

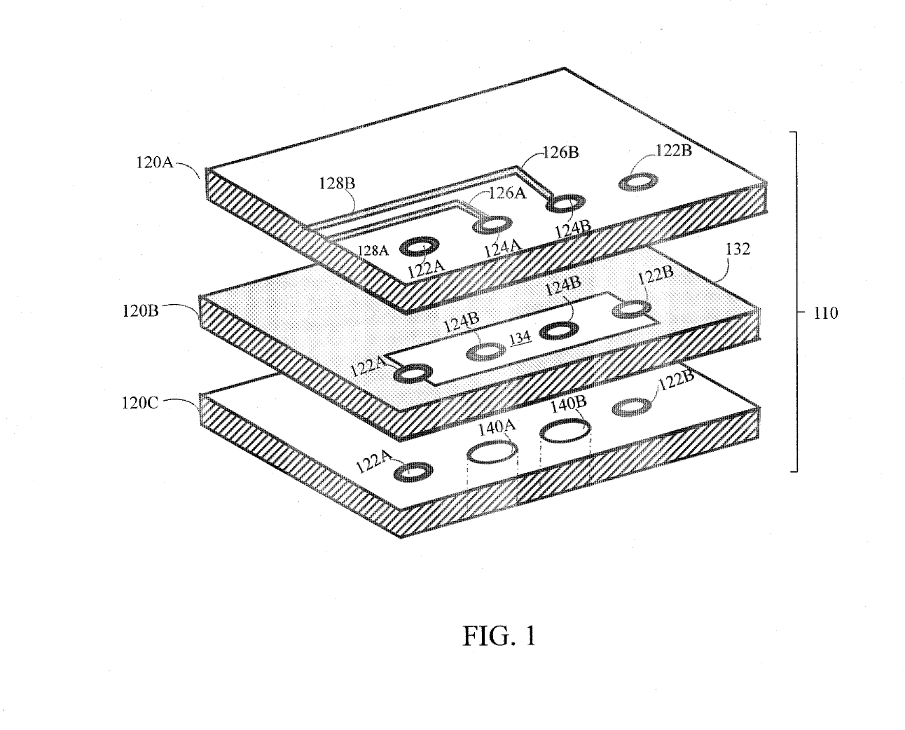

FIG. 1 schematically illustrates a printed circuit board 110. In this example, multiple layers of the printed circuit board are shown separated, such as they may exist prior to being fused into a unitary board. In this example, layers 120A, 120B and 120C are illustrated. For simplicity, only three layers are shown. However, it should be appreciated that a printed circuit board may contain more than three layers. In some embodiments, breakout regions will be formed in a back plane for an electronic system, which may contain ten or more layers. Similar construction techniques may be employed in these and other types of the printed circuit boards.

In this example, layer 120A is shown to contain multiple vias, of which vias 122A, 122B, 124A and 124B are shown. In this example, vias 122A and 122 are ground vias, which are connected through vias to ground planes. Vias 124A and 124B are signal vias, which are connected through vias to signal traces. These vias may form a portion of a component footprint. For example, contact tails of an electrical connector (not shown) may be inserted into vias 122A, 122B, 124A and 124B.

Though not shown, printed circuit board 110 may contain multiple additional vias as part of such a component footprint. Those vias may be positioned to leave routing channels through which traces making connections to signal vias may be routed. In this example, traces 128A and 128B may represent traces in a routing channel. In this example, trace 128A is coupled to a conducting portion of a via 124A. Trace 128B is coupled to a conducting portion of via 124B. Traces 128A and 128B are coupled to vias 124A and 124B, respectively, through breakout trace portions 126A and 126B.

Layer 120B is here illustrated as providing a ground plane. Layer 120B has a metallized coating 132 on its surface. As can be seen in FIG. 1, ground vias 122A and 122B have conducting portions in contact with layer 132. However, an antipad 134 is formed in layer 132 around signal vias 124A and 124B. Antipad 134 provides clearance around the signal vias to prevent them from being shorted to the ground plane.

Layer 120C represents a lower layer of the printed circuit board. Layer 120C may contain traces (not shown) connected to other vias (not shown). Layer 120C allows printed circuit board 110 to contain more traces than can be routed on layer 120A. If more signals are to be routed within back plane 120, further layers may be included. Additional layers may alternately provide a ground layer and a layer with signal traces. Though, any suitable construction technique may be used.

In this example, the ground vias 122A and 122B continue through layer 120C, and may continue through other layers if included in printed circuit board 110. The signal vias 124A and 124B may similarly continue through other layers of the printed circuit board. However, if no further connections are made to signal vias 124A and 124B at lower layer 120C or any layer below layer 120C, the conducting portions of the via need not be continued through those lower layers.

Rather, in some embodiments it may be desirable for the conducting portions of signal vias to not extend fully through printed circuit board 110. Printed circuit board construction techniques resulting in conducting portions of vias that do not extend fully through a printed circuit board are known. Any such construction technique may be used in forming a printed circuit board such as printed circuit board 110. As one example of such a technique, back drilling may be used. For back drilling, a larger diameter hole, such as holes 140A and 140B, may be drilled through a via. Drilling such a hole removes the conducting portion of the via. Though such a construction may be useful in constructing a high frequency printed circuit board, it is not a requirement of the invention that back drilling be used.

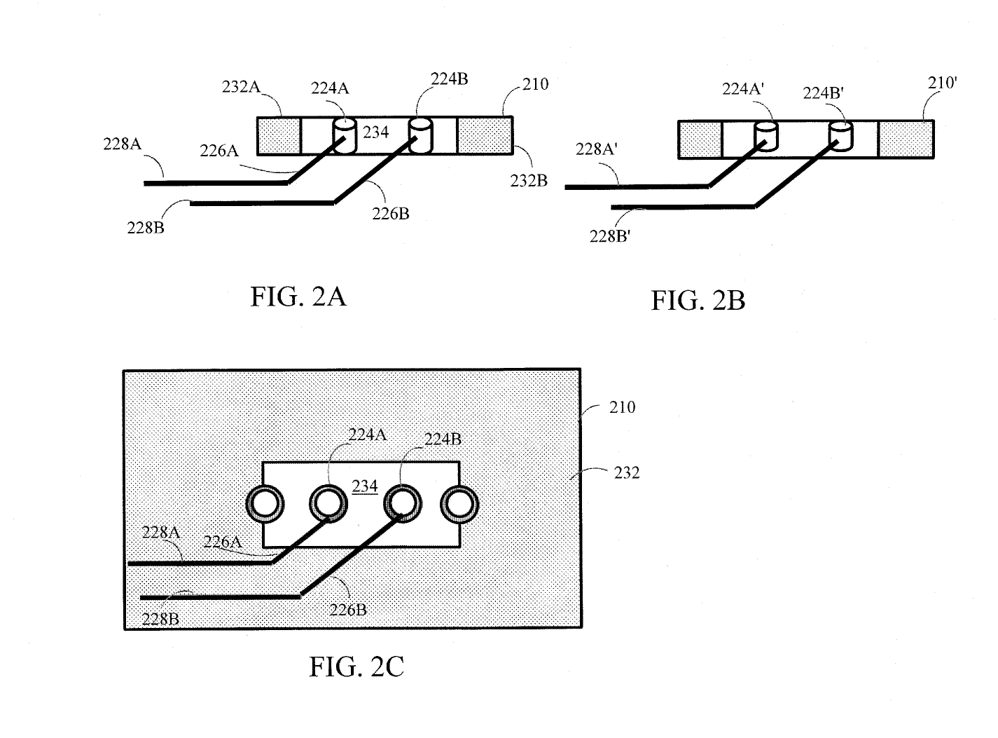

FIG. 2A schematically illustrates in cross section a portion of a printed circuit board 210 like the portion illustrated in FIG. 1. In this example, the printed circuit board 210 includes signal vias 224A and 224B. Each of the signal vias 224A and 224B is coupled to a trace 228A and 228B, respectively. The vias are coupled to breakout trace portions 226A and 226B, respectively. In this example, the signal traces and signal vias are configured to form differential pairs adapted for propagating a differential signal. Accordingly, breakout trace portions 226A and 226B may be designed to provide a desired differential impedance profile. This differential impedance may be determined based on the differential impedance of signal vias 224A and 224B and/or the differential impedance of traces 228A and 228B. In FIG. 2A, the ground vias and ground planes of the printed circuit boards are schematically illustrated as ground regions 232A and 232B that surround the signal vias. FIG. 2C shows a corresponding plan view of printed circuit board 210. As can be seen in FIG. 2C, an antipad 234 in ground plane 232 surrounds the signal vias 224A and 224B.

In a printed circuit board, the traces adapted for carrying signals are spaced from each other and from the ground planes to provide a nominal impedance. For differential pairs, the impedance may, for example, be in the range of 75 to 125 ohms. Though, a common configuration is for differential pairs to have a nominal differential impedance of 85 ohms or 100 ohms. Frequently, though, this nominal trace impedance is not maintained in the breakout region. As can be seen in FIG. 2C, at least a portion of breakout trace portions 226A and 226B passes over the antipad 234. These portions are therefore separated from the nearest ground structure by a different amount than the traces 228A and 228B outside the breakout regions. Accordingly, in a conventionally manufactured printed circuit board, multiple impedance discontinuities may exist across the breakout regions.

The vias may have a different impedance than the traces. Signal vias 224A and 224B, for example, may be formed with a different shape than the traces such that the impedance may be different than in the traces. For example, in a conventional printed circuit board, a via may conventionally have an impedance of 70 Ohms or less. The breakout trace portions 226A and 226B may have yet a further different impedance, creating multiple impedance discontinuities in the signal path between the vias 224A and 224B and the traces 228A and 228B.

FIG. 2B illustrates a printed circuit board 210 in cross section. In this example, signal vias 224A′ and 224B′ have been back drilled such that they do not extend fully through the thickness of printed circuit board 210A. Though, as can be seen from the similarities between FIGS. 2A and 2B, even when back drilling is used, multiple impedance transitions may exist in the signal paths between vias such as 224A′ and 224B′ and the corresponding traces 228A′ and 228B′ having the nominal trace impedance.

In accordance with some embodiments of the invention, values for one or more parameters of the structures in the breakout region may be selected to reduce the number of impedance discontinuities.

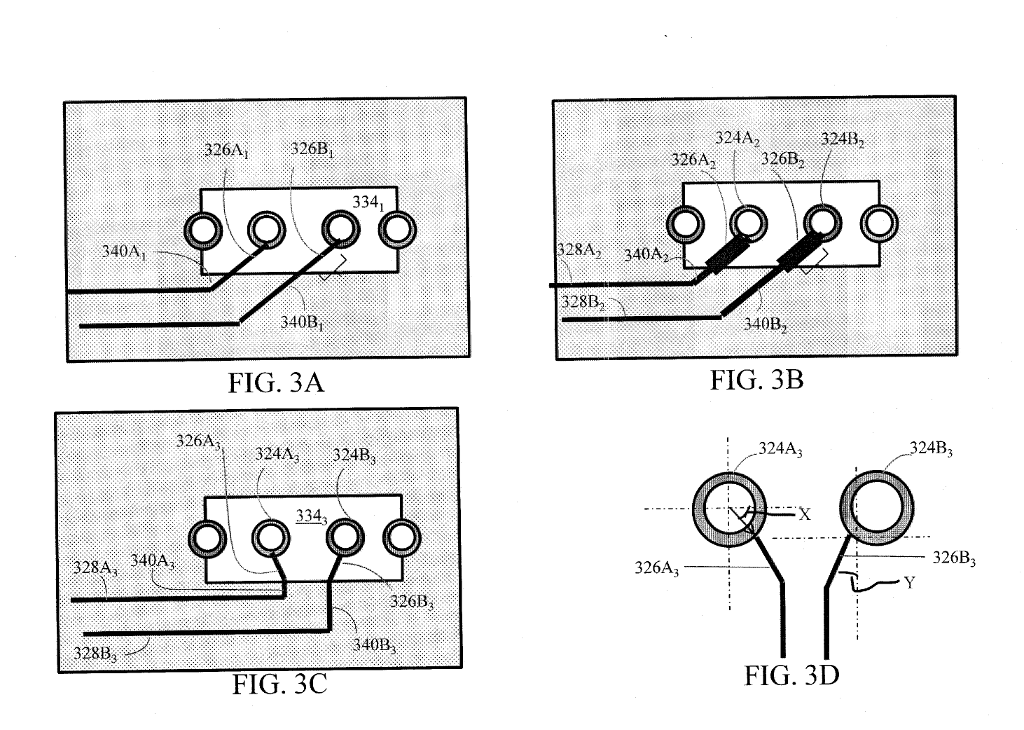

An example of a parameter that may be varied is the width of a portion of a trace. FIG. 3A illustrates, in plan view, a breakout region of a printed circuit board. In this example, traces exiting the breakout region have breakout subportions 326A₁ and 326B₁. These subportions overlay antipad 334₁. In comparison to subportions 340A₁ and 340B₁, which overlay the ground plane, subportions 326A₁ and 326B₁ may have a different impedance because they are separated by a different amount from a ground plane.

FIG. 3B shows that, to avoid an impedance discontinuity, subportions of the breakout trace portions 326A₂ and 326B₂ overlaying the antipad may have a different width. In this example, they are shown to be wider than an adjacent subportion 340A₂ and 340B₂. The width may be selected such that the impedance of subportions 326A₂ and 326B₂ is consistent with the impedance of the signal path through vias 324A₂ and 324B₂. Any suitable technique may be used to select a value of a width perimeter of a trace to achieve a desired impedance. For example, electrical simulation tools are commercially available and may be used to either solve an equation relating the desired impedance to a trace width or to iteratively compute an impedance for multiple trace widths until a trace width providing a desired impedance is identified. A computer simulation tool may be used for this purpose.

The subportions 340A₂ and 340B₂ of the breakout trace portions may be designed to have the same impedance as subportions 326A₂ and 326B₂. Alternatively, subportions 340A₂ and 340B₂ may be designed to have the same impedance as traces 328A₂ and 328B₂. In either event, the signal path between vias 324A₂ and 324B₂ and traces 328A₂ and 328B₂ may have a limited number of impedance discontinuities. Specifically in this example, the trace widths of subportions 340A₂ and 340B₂ are selected to provide matching impedance in comparison to subportions 326A₂ and 326B₂. The impedances of both subportions may be selected to match the impedance of either vias 324A₂ and 324B₂ or of traces 328A₂ and 328B₂. In this example, the differential impedances of both subportions are selected to match the differential impedance of vias 324A₂ and 324B₂. The widths for subportions 340A₂ and 340B₂, as with the selection of values for other perimeters in the design of the breakout region of a printed circuit board, may be selected using computerized simulation tools.

In this example, the widths of subportions 340A₂ and 340B₂ are selected to provide a consistent impedance between subportions 326A₂ and 326B₂, on the one hand, and subportions 340A₂ and 340B₂, on the other hand. In this way, no significant impedance discontinuity exists between the subportions of the breakout region. Accordingly, the signal path between vias 324A₂ and 324B₂ is generally free of impedance discontinuities until the signal path reaches traces 328A₂ and 328B₂. In this example, traces 328A₂ and 328B₂, which here are shown as running in an a routing channel, have a different impedance than in the breakout region. Though there is an impedance discontinuity between the breakout regions and signal traces 328A₂ and 328B₂, having one impedance discontinuity as illustrated in the example of FIG. 3B, rather than two impedance discontinuities, as illustrated in FIG. 3A, may provide for a flatter insertion loss profile for signals propagating through the vias to the traces.

It should be appreciated that, though FIG. 3B shows subportions 326A₂ and 326B₂ as having uniform width, that is not a requirement of the invention. The width of portions of the traces in the breakout regions, including portions such as subportions 326A₂ and 326B₂, may vary. As a specific example, the width may vary so as to create tapered subportions. For example, the subportions may be narrower adjacent to vias 324A₂ and 324B₂, increasing in width towards the opposite end. FIG. 3C illustrates a further example of a technique for varying values of a parameter in the breakout region to reduce a number of impedance discontinuities. In the example of FIG. 3C, an angle at which traces exit the vias in the breakout region may be varied. In this example, subportions 326A₃ and 326B₃ exit vias 326A₃ and 326B₃ at angles that cause subportions 326A₃ and 326B₃ to converge within the portion of the breakout region aligned with antipad 334₃. Changing the spacing of the traces as well as the amount of the trace passing over antipad 334₃ may impact the impedance of subportions 326A₃ and 326B₃. Values of a parameter defining an exit angle may be varied, as part of designing the breakout region, until a desired impedance is achieved. In this example, these values may be selected to achieve an impedance along a signal path in subportions 326A₃ and 326B₃ that is consistent with the impedance of the signal path through vias 324A₃ and 324B₃.

In this example, subportions 340A₃ and 340B₃ may be designed to have an impedance that is consistent with the impedance of the signal path along traces 328A₃ and 328B₃ in a routing channel of the footprint. In this way, a single impedance discontinuity may exist in the breakout region. Though, in other embodiments, values for parameters of subportions 340A₃ and 340B₃ may be selected to provide an impedance consistent with the impedance in subportions 326A₃ and 326B₃. Either embodiment may result in a limited number of impedance discontinuity that provides a flat insertion loss profile that provides desirable high frequency performance of an interconnection system using a breakout region.

FIG. 3D illustrates a portion of the breakout region of FIG. 3C surrounding vias 324A₃ and 324B₃. FIG. 3D illustrates angular parameters that may be varied. For example, subportion 326A₃ is shown exited via 324A₃. The angular location around via 324A₃ at which subportion 326A₃ exits via 324A₃ is identified by the angle X. The value of the angle X may be varied to alter the impedance of the single path through the breakout region.

FIG. 3D illustrates that subportion 326B₃ runs at an angle Y as it exits via 324B₃. The angles X and Y may be measured relative to any suitable reference direction. In this example, the vias forming a component footprint are laid out in rows, which may define a reference direction. The angles X and Y, for example, may be measured relative to the direction of the rows. Alternatively, the angles X and Y may be measured relative to a direction perpendicular to the rows. Regardless of how the angles X and Y are measured, varying values for these parameters may adjust the impedance of the breakout regions such that varying values of these parameters may lead to a design of the breakout region that provides a desirable insertion loss profile.

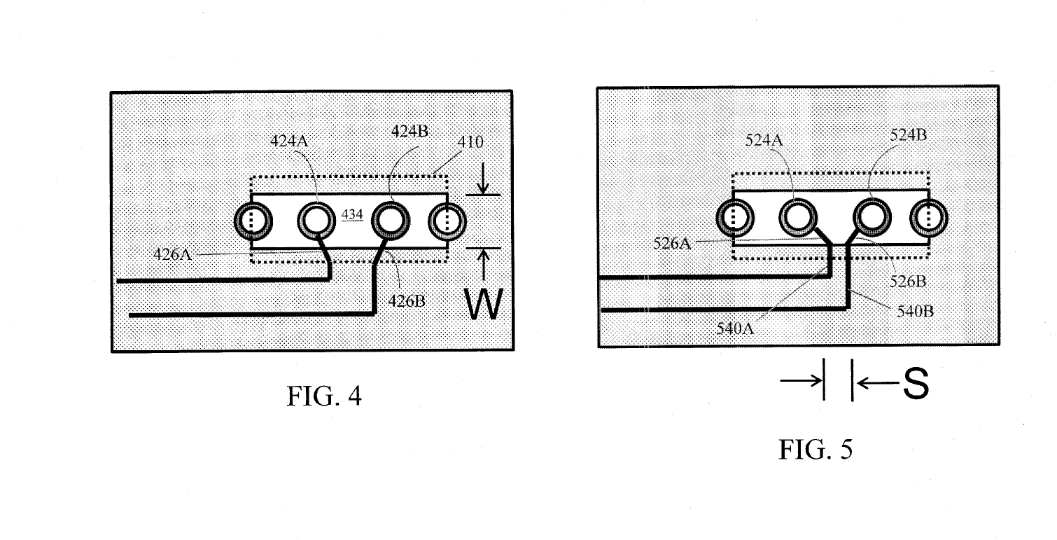

FIG. 4 illustrates an example of a further parameter that may be selected to provide a desired impedance profile in a breakout region. In this example, the width, W, of antipad 434 has been varied. In this example, the size of antipad 334₃ is shown by phantom outline 410. As can be seen, antipad 434 has a width, W, narrower than antipad 334₃. Changing the width of antipad 434 may alter the impedance of vias 424A and 424B. Alternatively or additionally, varying the width of antipad 434 may alter the amount of breakout trace portions 426A and 426B adjacent antipad 434, which may in turn alter the impedance of breakout portions 426A and 426B.

FIG. 5 illustrates a further example of a parameter that may be selected to provide a desired impedance profile. FIG. 5 shows a breakout region around vias 524A and 524B. In this example, the spacing, S, between subportions 540A and 540B is selected such that subportions 540A and 540B have an impedance consistent with the impedance of the adjacent subportions 526A and 526B. In the embodiment illustrated, the impedance of both subportions 526A and 526B and the impedance of subportions 540A and 540B may be selected to match the impedance of vias 524A and 524B.

FIGS. 3A, 3B, 3C, 3D, FIG. 4 and FIG. 5 illustrate examples of parameters that may be varied to provide a desired impedance profile. In any breakout region, any one or more of these parameters may be selected to provide a desired impedance profile.

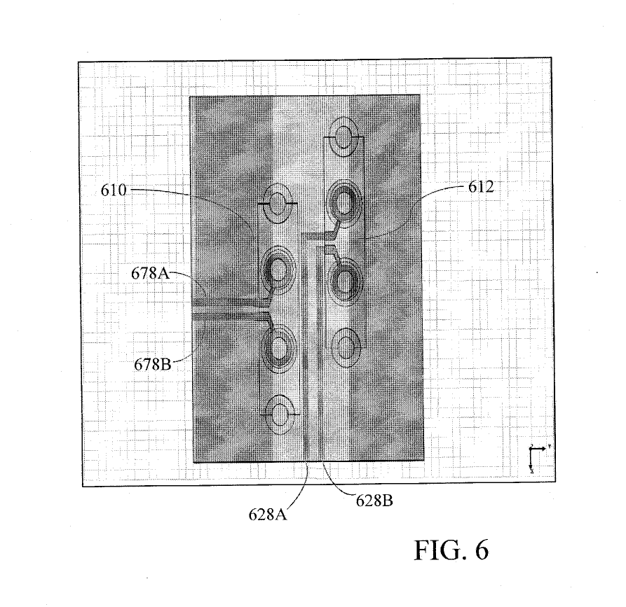

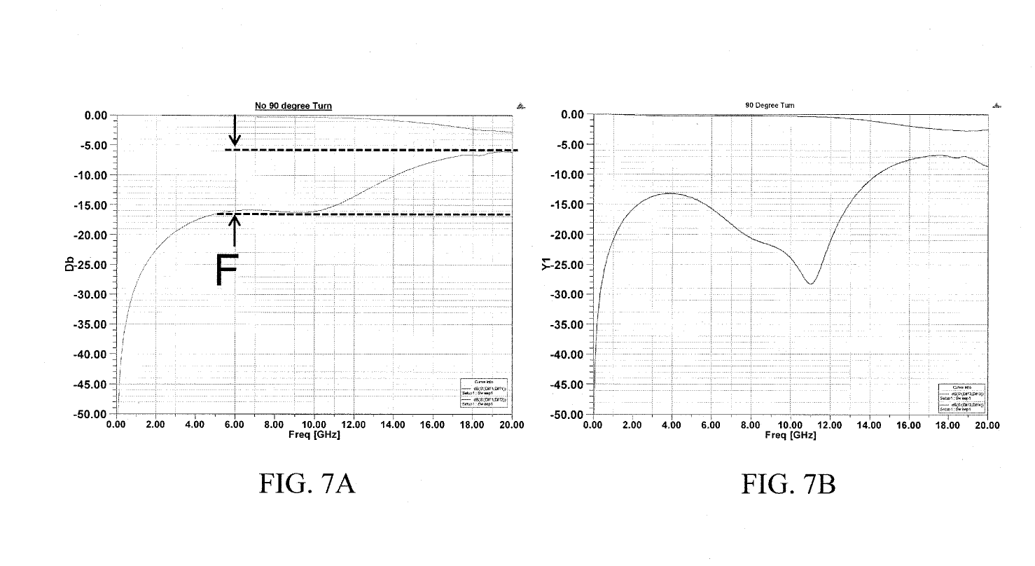

FIG. 6 illustrates a portion of a component footprint, including breakout regions 610 and 612. FIG. 6 illustrates that values of design parameters may be selected for breakout regions regardless of the direction in which traces exit the breakout regions. In this example, traces 678A and 678B exit breakout region 610 without making a right angle turn. In contrast, traces 628A and 628B exit breakout region 612 with a 90 degree turn. FIGS. 7A and 7B illustrate that, by appropriate selection of values of the parameters of the breakout region, a desirable insertion loss profile may be achieved, regardless of whether the traces make a 90 degree turn. FIG. 7A illustrates the insertion loss profile from breakout region 610 in which the traces 628A and 678B do not make a 90 degree turn. In this example, the insertion loss is relatively flat over a frequency range corresponding to that used for high speed digital data signals. In this specific example, the insertion loss varies approximately 10 dB over a frequency range of approximately 6 GHz to approximately 20 GHz. Such a flatness, F, of an insertion loss profile may lead to desirable performance of an interconnection system carrying high speed data signals.

Any suitable criteria may be used to assess suitable flatness. Flatness may be expressed in terms of dB, and, for example, flatness of 5 dB, 10 dB, 15 dB or 20 dB may be acceptable in various embodiments. Likewise the frequency range over which flatness is measured may depend on operating characteristics for an electronic system in which a printed circuit board is used. The range, for example, may span frequency ranges of interest and may be, for example 10 GHz such as between 6 GHz and 16 GHz. Though, the range could be 8 GHz and be centered at any suitable frequency.

FIG. 7B illustrates a corresponding insertion loss profile for a breakout region, such as breakout region 612, in which the traces make a 90 degree turn. As can be seen in FIG. 7B, the 90 degree turn in the traces may introduce variations in the insertion loss profile. Nonetheless, the variation in insertion loss across a range of frequencies of interest may be relatively low in comparison to designs in which values of design parameters in the breakout region are not selected to provide a limited number of impedance discontinuities.

It should be appreciated at FIGS. 7A and 7B provide an example of the type of flat insertion loss profiles that may be achieved by selecting values of design parameters in the breakout region. Other values of design parameters may result in other insertion loss profiles. For example, in some embodiments, insertion loss may vary 15 dB or less over a frequency span of 10 GHz. Though, in other embodiments, the variation may be 10 dB or less over a corresponding frequency range.

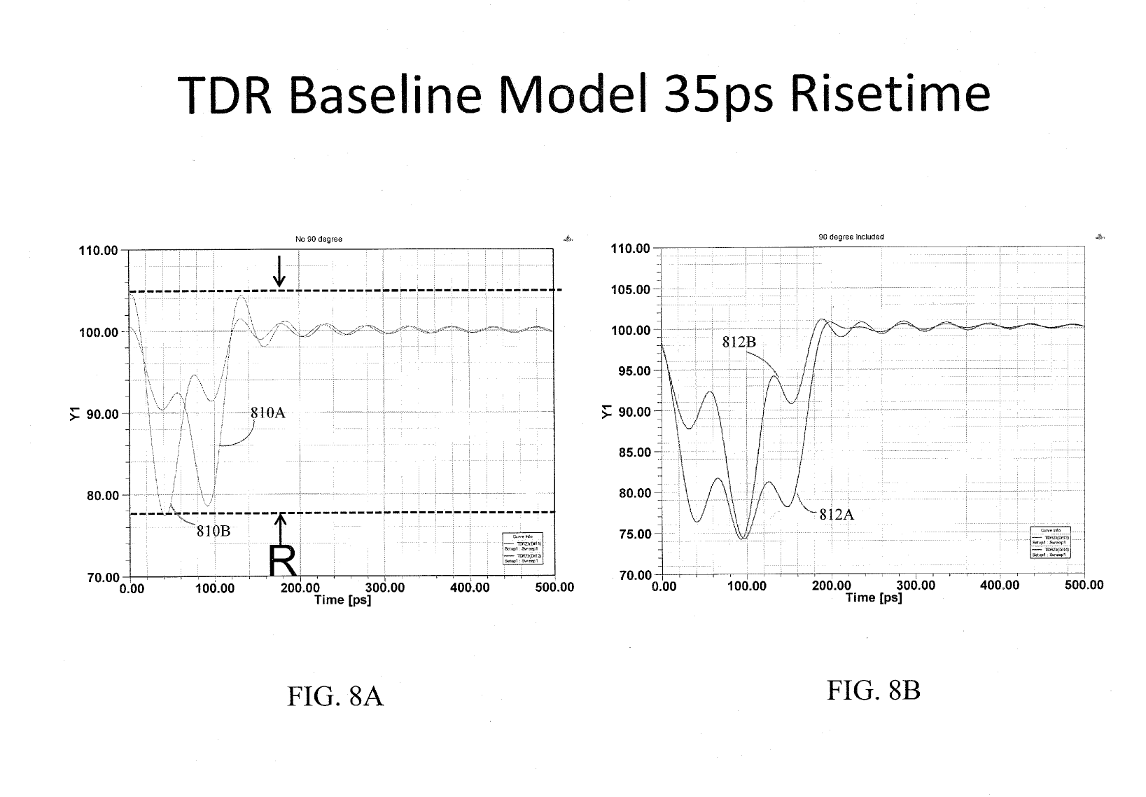

FIGS. 8A and 8B illustrate, through a different type of measurement, an effect of selecting an impedance profile with a limited number of impedance discontinuities. FIGS. 8A and 8B illustrate time domain reflectometry plots of signals injected into a breakout region in which values of design parameters have been selected to limit the number of impedance discontinuities. FIG. 8A illustrates a time domain reflectometry plot in which a signal with a 35 picosecond rise time has been injected into a breakout region. Curve 810A illustrates the time domain reflectometry (TDR) plot for a signal injected into the via. Curve 810B is a corresponding TDR plot for a signal injected into the trace side of the breakout region.

FIG. 8A illustrates the TDR plot for a breakout region 610 in which the traces do not make a 90 degree turn.

FIG. 8B illustrates a corresponding TDR plot for breakout region 612 in which the traces make a 90 degree turn. In FIG. 8B, line 812A corresponds to a TDR plot for a signal injected into the via. Line 812B is the TDR plot for a signal injected into the trace of the breakout region.

As shown in FIG. 8A, the TDR plot illustrates that the breakout region causes ringing of the signal. This ringing is illustrated by the variations of amplitude R after the signal is injected but before it settles to its final value, which is illustrated as 100 percent in the curve of FIG. 8A. In this example, the ringing is shown to be approximately 30 percent of the final value. FIG. 8B shows a comparable amount of ringing. Though, it should be appreciated that FIGS. 8A and 8B are just an example of the level of ringing that may be achieved by selecting values of design parameters in the breakout region. In other embodiments, different levels of ringing may be achieved. For example, for a signal with 35 picosecond rise time, in some embodiments, the ringing may be 40 percent or less. In yet other embodiments, the ringing may be 25 percent or less.

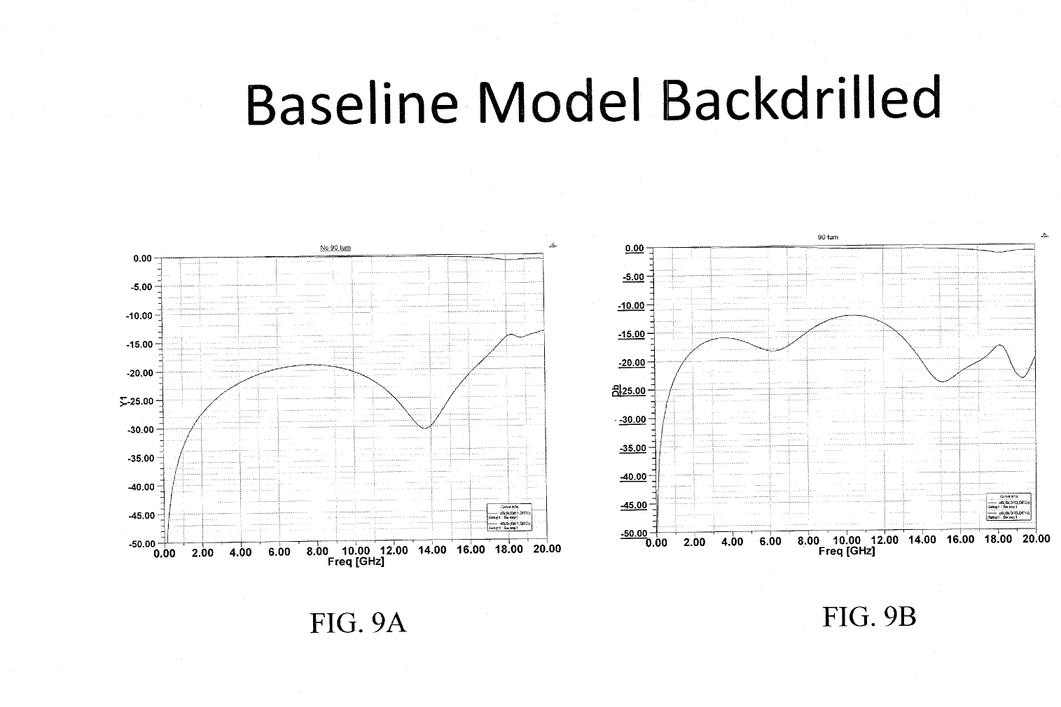

FIGS. 9A and 9B illustrate that a relatively flat insertion loss profile may be achieved by reducing the number of impedance discontinuities in the breakout region, even when back drilling is used. FIG. 9A illustrates the insertion loss for a breakout region, such as breakout region 610, when back drilling is used. FIG. 9B illustrates the insertion loss of a breakout region, such as breakout region 612, in which traces make a 90 degree turn and back drilling is used. As can be seen from a comparison of FIGS. 7A and 7B with FIGS. 9A and 9B, using back drilling may reduce the overall insertion loss while preserving the relative flatness of the insertion loss profile over a range of frequencies that may be employed when high speed data signals are passed through the breakout region.

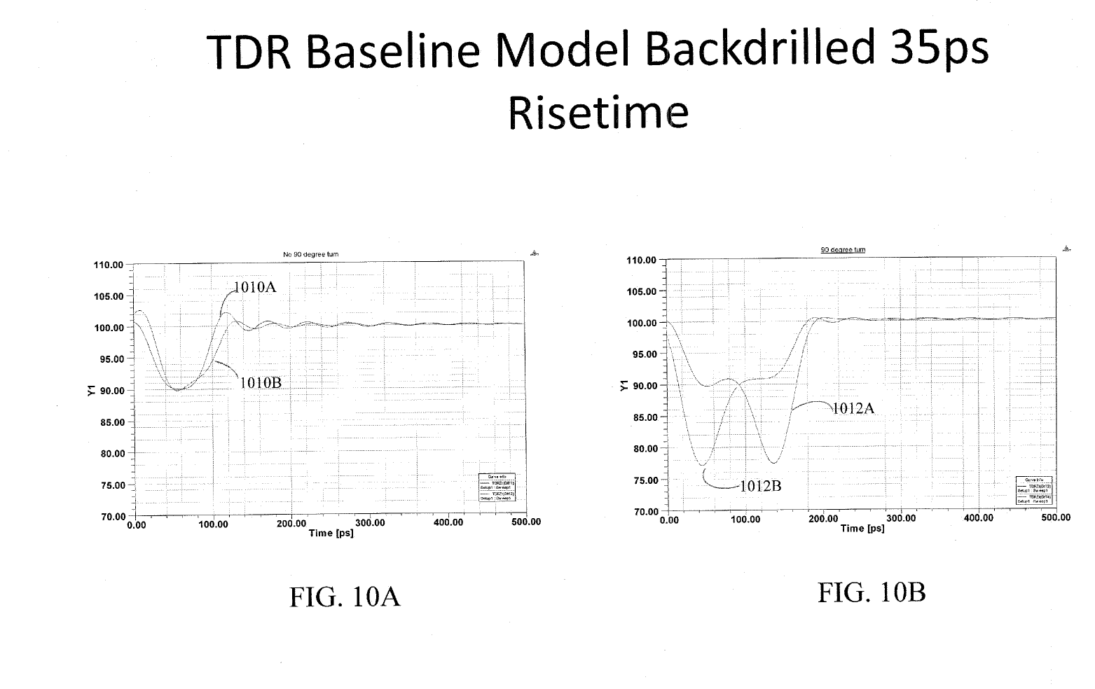

FIGS. 10A and 10B illustrate that the total amount of ringing may also be reduced when back drilling is used. FIG. 10A is a TDR plot of a breakout region, such as breakout region 610, when back drilling is used. The line 1010A represents the TDR plot for a signal with 35 picosecond rise time injected into the breakout region from the via. Line 1010B is the TDR plot for a signal with 35 picosecond rise time injected into the breakout region from the trace.

FIG. 10B is a TDR plot for a breakout region, such as breakout region 612, in which traces exit the breakout region at a 90 degree angle. Line 1012A represents the TDR plot for a signal with 35 picosecond rise time injected into the via. Line 1012B is a TDR plot for a signal with 35 picosecond rise time injected into the breakout region from the trace.

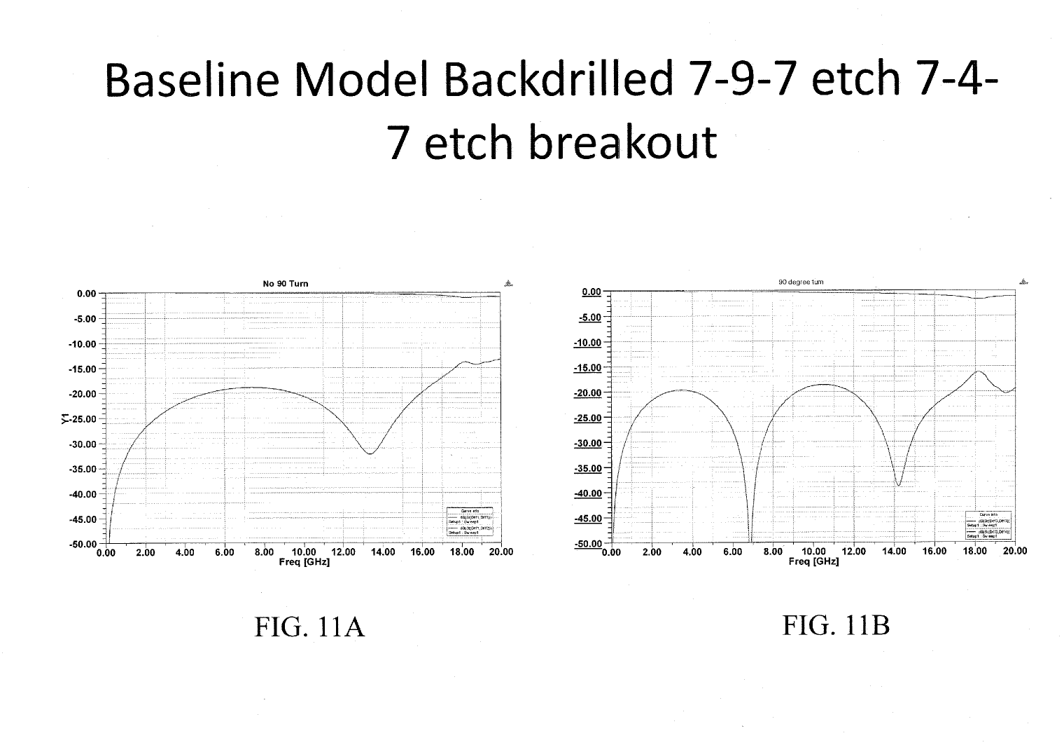

FIGS. 11A and 11B illustrate performance that can be achieved with printed circuit boards of other design parameters when the design parameters in the breakout region are selected to limit the number of impedance discontinuities. In the examples of FIGS. 11A and 11B, the printed circuit board has breakout regions in which the signal vias are back drilled, and the traces are made with 7-9-7 etch. In the breakout region, the trace subportions are made with 7-4-7 etch. FIG. 11A represents an insertion loss profile for a breakout region, such as breakout region 610, in which the traces do not make a right angle turn. FIG. 11B represents insertion loss for a breakout region, such as breakout region 612, in which the traces make a right angle turn.

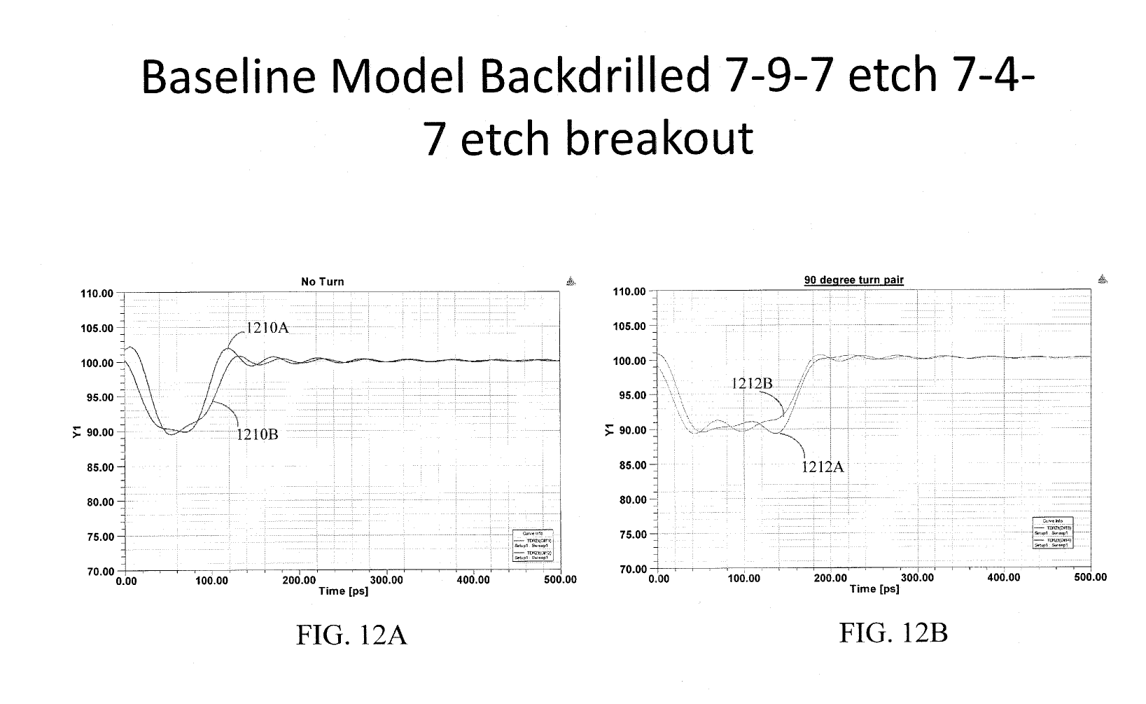

FIGS. 12A and 12B are TDR plots for breakout regions formed under the same conditions as in FIGS. 11A and 11B. In FIG. 12A, the line 1210A represents the TDR plot for a 35 picosecond rise time signal injected into the breakout region from the via. Line 1210B represents the TDR plot for the signal injected into the breakout region from the signal trace. In FIG. 12B, line 1212A represents the TDR plot of a signal injected into the breakout region from the via, and line 1212B is the TDR plot of the signal injected into the breakout region from the trace.

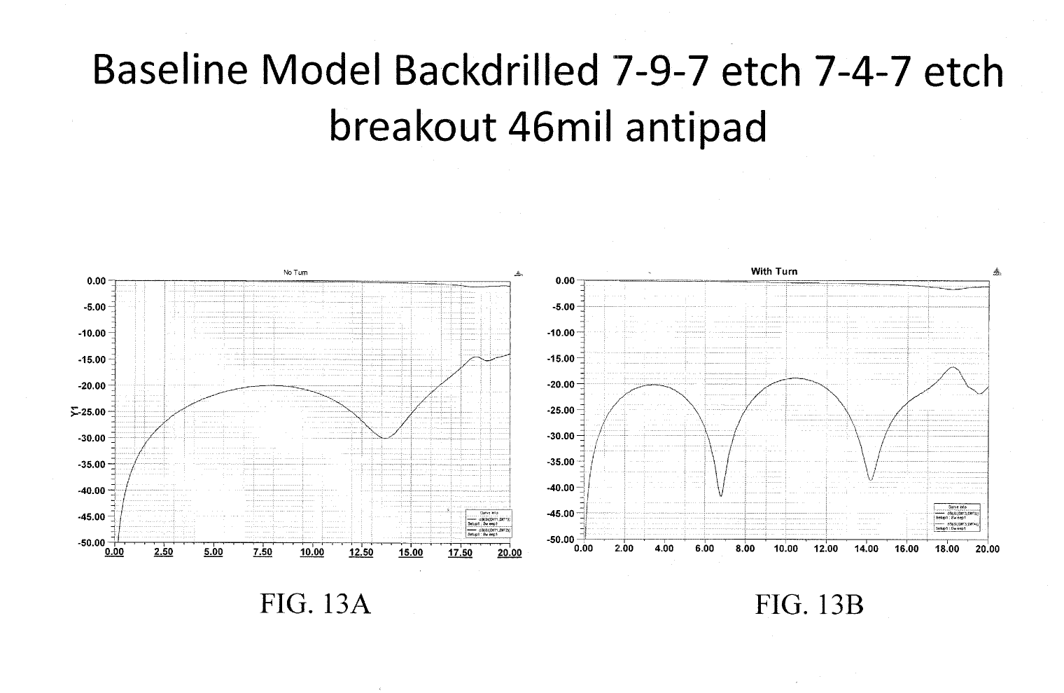

FIGS. 13A and 13B illustrate that desirable performance may be achieved by selecting values of other parameters. FIGS. 13A and 13B are insertion loss profiles for breakout regions in which the antipad has a width of 46 mils. FIG. 13A corresponds to a breakout region, such as breakout region 610, in which the traces exit the breakout region without a right angle turn. FIG. 13B corresponds to a breakout region, such as breakout region 612, in which the traces exit the breakout region with a 90 degree turn.

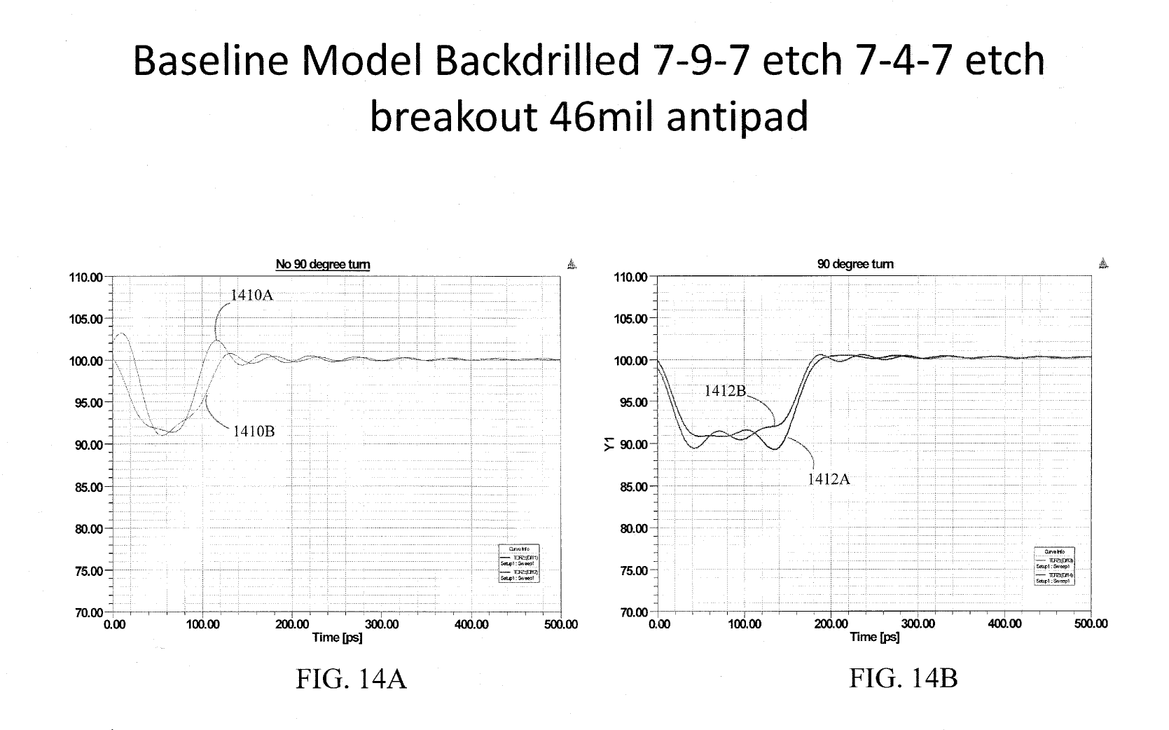

FIGS. 14A and 14B are TDR plots of breakout regions formed under the conditions corresponding to the conditions under which the plots of FIGS. 13A and 13B were formed. FIG. 14A is a TDR plot for a breakout region, such as breakout region 610, in which the traces exit the breakout region without making a 90 degree turn. Line 1410A represents the TDR plot for a signal injected into the breakout region from the via. Line 1410B is the TDR plot of a signal injected into the breakout region from the trace. FIG. 14B is a TDR plot for a breakout region, such as breakout region 612, in which the traces exit the breakout region with a 90 degree turn. In this example, line 1412A is the TDR plot of a signal injected into the breakout region from the via. Line 1412B is the TDR plot of a signal injected into the breakout region from the trace.

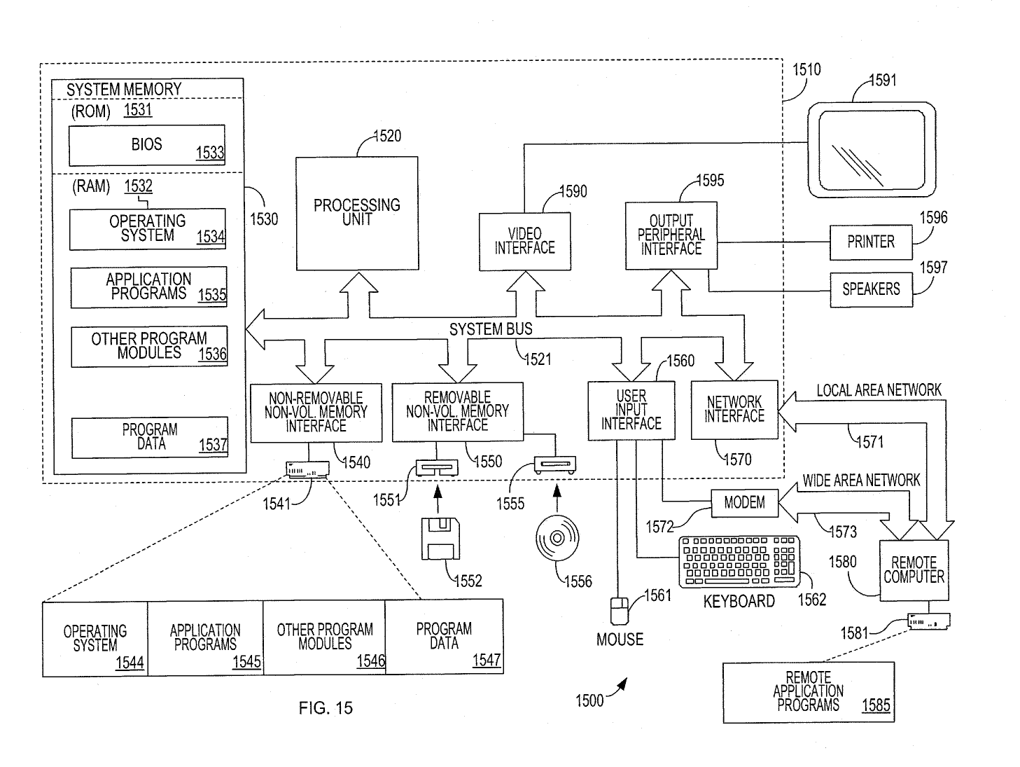

FIG. 15 illustrates an example of a suitable computing system environment 1500 on which the invention may be implemented. Such a computing system may be used to execute a computerized tool to aid a printed circuit board designer select values of parameters for the breakout regions to achieve impedance profiles as described above. Such a tool may use known electromagnetic simulation techniques to compute impedance values of vias and traces connected to them. Those techniques may also be used to compute the impedance of the breakout regions interconnecting the traces and the vias. Such a capability may be used in a computerized tool that aids in the selection of values of design parameters in the breakout region.

As a specific example, a tool may be configured to iteratively vary values of one or more design parameters in the breakout region and recompute the impedance profile of the breakout region. The process may be repeated iteratively until a set of values for the parameters yields a desired impedance profile. Though, any suitable computational technique may be used to identify appropriate values of the parameters. Output generated by such a tool may be captured in any suitable way. In some embodiments the output is captured in a printed circuit board design file of a known type. Such a design file may then be provided to a printed circuit board manufacturer. The manufacturer may use the design file to create masks to pattern layers of a printed circuit board such that, when the layers are fused into a board, the board has breakout regions, each with an impedance profile to provide improved high frequency performance.

The computing system environment 1500 is only one example of a suitable computing environment and is not intended to suggest any limitation as to the scope of use or functionality of the invention. Neither should the computing environment 1500 be interpreted as having any dependency or requirement relating to any one or combination of components illustrated in the exemplary operating environment 1500.

The invention is operational with numerous other general purpose or special purpose computing system environments or configurations. Examples of well known computing systems, environments, and/or configurations that may be suitable for use with the invention include, but are not limited to, personal computers, server computers, hand-held or laptop devices, multiprocessor systems, microprocessor-based systems, set top boxes, programmable consumer electronics, network PCs, minicomputers, mainframe computers, distributed computing environments that include any of the above systems or devices, and the like.

The computing environment may execute computer-executable instructions, such as program modules. Generally, program modules include routines, programs, objects, components, data structures, etc. that perform particular tasks or implement particular abstract data types. The invention may also be practiced in distributed computing environments where tasks are performed by remote processing devices that are linked through a communications network. In a distributed computing environment, program modules may be located in both local and remote computer storage media including memory storage devices.

FIG. 15 illustrates an example of a suitable computing system environment 1500 on which the invention may be implemented. The computing system environment 1500 is only one example of a suitable computing environment and is not intended to suggest any limitation as to the scope of use or functionality of the invention. Neither should the computing environment 1500 be interpreted as having any dependency or requirement relating to any one or combination of components illustrated in the exemplary operating environment 1500.

The invention is operational with numerous other general purpose or special purpose computing system environments or configurations. Examples of well known computing systems, environments, and/or configurations that may be suitable for use with the invention include, but are not limited to, personal computers, server computers, hand-held or laptop devices, multiprocessor systems, microprocessor-based systems, set top boxes, programmable consumer electronics, network PCs, minicomputers, mainframe computers, distributed computing environments that include any of the above systems or devices, and the like.

The computing environment may execute computer-executable instructions, such as program modules. Generally, program modules include routines, programs, objects, components, data structures, etc. that perform particular tasks or implement particular abstract data types. The invention may also be practiced in distributed computing environments where tasks are performed by remote processing devices that are linked through a communications network. In a distributed computing environment, program modules may be located in both local and remote computer storage media including memory storage devices.

With reference to FIG. 15, an exemplary system for implementing the invention includes a general purpose computing device in the form of a computer 1510. Components of computer 1510 may include, but are not limited to, a processing unit 1520, a system memory 1530, and a system bus 1521 that couples various system components including the system memory to the processing unit 1520. The system bus 1521 may be any of several types of bus structures including a memory bus or memory controller, a peripheral bus, and a local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus also known as Mezzanine bus.

Computer 1510 typically includes a variety of computer readable media. Computer readable media can be any available media that can be accessed by computer 1510 and includes both volatile and nonvolatile media, removable and non-removable media. By way of example, and not limitation, computer readable media may comprise computer storage media and communication media. Computer storage media includes both volatile and nonvolatile, removable and non-removable media implemented in any method or technology for storage of information such as computer readable instructions, data structures, program modules or other data. Computer storage media includes, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which can be used to store the desired information and which can accessed by computer 1510. Communication media typically embodies computer readable instructions, data structures, program modules or other data in a modulated data signal such as a carrier wave or other transport mechanism and includes any information delivery media. The term “modulated data signal” means a signal that has one or more of its characteristics set or changed in such a manner as to encode information in the signal. By way of example, and not limitation, communication media includes wired media such as a wired network or direct-wired connection, and wireless media such as acoustic, RF, infrared and other wireless media. Combinations of the any of the above should also be included within the scope of computer readable media.

The system memory 1530 includes computer storage media in the form of volatile and/or nonvolatile memory such as read only memory (ROM) 1531 and random access memory (RAM) 1532. A basic input/output system 1533 (BIOS), containing the basic routines that help to transfer information between elements within computer 1510, such as during start-up, is typically stored in ROM 1531. RAM 1532 typically contains data and/or program modules that are immediately accessible to and/or presently being operated on by processing unit 1520. By way of example, and not limitation, FIG. 15 illustrates operating system 1534, application programs 1535, other program modules 1536, and program data 1537.

The computer 1510 may also include other removable/non-removable, volatile/nonvolatile computer storage media. By way of example only, FIG. 15 illustrates a hard disk drive 1541 that reads from or writes to non-removable, nonvolatile magnetic media, a magnetic disk drive 1551 that reads from or writes to a removable, nonvolatile magnetic disk 1552, and an optical disk drive 1555 that reads from or writes to a removable, nonvolatile optical disk 1556 such as a CD ROM or other optical media. Other removable/non-removable, volatile/nonvolatile computer storage media that can be used in the exemplary operating environment include, but are not limited to, magnetic tape cassettes, flash memory cards, digital versatile disks, digital video tape, solid state RAM, solid state ROM, and the like. The hard disk drive 1541 is typically connected to the system bus 1521 through an non-removable memory interface such as interface 1540, and magnetic disk drive 1551 and optical disk drive 1555 are typically connected to the system bus 1521 by a removable memory interface, such as interface 1550.

The drives and their associated computer storage media discussed above and illustrated in FIG. 15, provide storage of computer readable instructions, data structures, program modules and other data for the computer 1510. In FIG. 15, for example, hard disk drive 1541 is illustrated as storing operating system 1544, application programs 1545, other program modules 1546, and program data 1547. Note that these components can either be the same as or different from operating system 1534, application programs 1535, other program modules 1536, and program data 1537. Operating system 1544, application programs 1545, other program modules 1546, and program data 1547 are given different numbers here to illustrate that, at a minimum, they are different copies. A user may enter commands and information into the computer 1510 through input devices such as a keyboard 1562 and pointing device 1561, commonly referred to as a mouse, trackball or touch pad. Other input devices (not shown) may include a microphone, joystick, game pad, satellite dish, scanner, or the like. These and other input devices are often connected to the processing unit 1520 through a user input interface 1560 that is coupled to the system bus, but may be connected by other interface and bus structures, such as a parallel port, game port or a universal serial bus (USB). A monitor 1591 or other type of display device is also connected to the system bus 1521 via an interface, such as a video interface 1590. In addition to the monitor, computers may also include other peripheral output devices such as speakers 1597 and printer 1596, which may be connected through a output peripheral interface 1595.

The computer 1510 may operate in a networked environment using logical connections to one or more remote computers, such as a remote computer 1580. The remote computer 1580 may be a personal computer, a server, a router, a network PC, a peer device or other common network node, and typically includes many or all of the elements described above relative to the computer 1510, although only a memory storage device 1581 has been illustrated in FIG. 15. The logical connections depicted in FIG. 15 include a local area network (LAN) 1571 and a wide area network (WAN) 1573, but may also include other networks. Such networking environments are commonplace in offices, enterprise-wide computer networks, intranets and the Internet.

When used in a LAN networking environment, the computer 1510 is connected to the LAN 1571 through a network interface or adapter 1570. When used in a WAN networking environment, the computer 1510 typically includes a modem 1572 or other means for establishing communications over the WAN 1573, such as the Internet. The modem 1572, which may be internal or external, may be connected to the system bus 1521 via the user input interface 1560, or other appropriate mechanism. In a networked environment, program modules depicted relative to the computer 1510, or portions thereof, may be stored in the remote memory storage device. By way of example, and not limitation, FIG. 15 illustrates remote application programs 1585 as residing on memory device 1581. It will be appreciated that the network connections shown are exemplary and other means of establishing a communications link between the computers may be used.

Having thus described several aspects of at least one embodiment of this invention, it is to be appreciated that various alterations, modifications, and improvements will readily occur to those skilled in the art.

For example, in some embodiments, a breakout region may be said to have an impedance “matched to” or “consistent with” another structure such as a via. It should be appreciated that these impedances need not be identical. To the contrary, impedances may be matched if, over some frequency range of interest, or at a nominal frequency of interest, the impedances differ by less than some threshold amount. The threshold may be specified as a relative value, such as a percentage difference. As an example, impedances in some embodiments may be considered matched if they differ by less than 5%. Though, in other embodiments, differences of up to 10%, 15% or 20% may be regarded as matched. The differences regarded as acceptable in any specific embodiment may depend on whether such a change in impedance creates a reflection large enough to be significant in impacting performance of an electronic device. Accordingly, it shall be appreciated that the specific threshold used in regarding impedances as “matched” or “consistent” is not critical to the invention.

In other embodiments, the threshold may be specified in terms of Ohms. For example, a difference of 50 Ohms or less may be regarded as matched. In other embodiments, differences of 10 Ohms, 15 Ohms or 20 Ohms may be regarded as “matched” or “consistent.”

In this context, a frequency of interest may be determined based on the data rate of signals to pass through a footprint. The frequency of interest may be the principal frequency of highest speed signal. Though, the range could span frequencies of one or more harmonics of such signals.

Further, it should be recognized that multiple parameters for which values may be selected have been described. Though not every combination of these parameters has been expressly illustrated, in some embodiments values for any one or more parameters may be selected to provide desired electrical properties. Accordingly, it should be appreciated that embodiments may encompass printed circuit boards, and design and manufacture techniques for such printed circuit boards, that entail selection of values for any combination of the above-described parameters.

Such alterations, modifications, and improvements are intended to be part of this disclosure, and are intended to be within the spirit and scope of the invention. Further, though advantages of the present invention are indicated, it should be appreciated that not every embodiment of the invention will include every described advantage. Some embodiments may not implement any features described as advantageous herein and in some instances. Accordingly, the foregoing description and drawings are by way of example only.

The above-described embodiments of the present invention can be implemented in any of numerous ways. For example, the embodiments may be implemented using hardware, software or a combination thereof. When implemented in software, the software code can be executed on any suitable processor or collection of processors, whether provided in a single computer or distributed among multiple computers. Such processors may be implemented as integrated circuits, with one or more processors in an integrated circuit component. Though, a processor may be implemented using circuitry in any suitable format.

Further, it should be appreciated that a computer may be embodied in any of a number of forms, such as a rack-mounted computer, a desktop computer, a laptop computer, or a tablet computer. Additionally, a computer may be embedded in a device not generally regarded as a computer but with suitable processing capabilities, including a Personal Digital Assistant (PDA), a smart phone or any other suitable portable or fixed electronic device.

Also, a computer may have one or more input and output devices. These devices can be used, among other things, to present a user interface. Examples of output devices that can be used to provide a user interface include printers or display screens for visual presentation of output and speakers or other sound generating devices for audible presentation of output. Examples of input devices that can be used for a user interface include keyboards, and pointing devices, such as mice, touch pads, and digitizing tablets. As another example, a computer may receive input information through speech recognition or in other audible format.

Such computers may be interconnected by one or more networks in any suitable form, including as a local area network or a wide area network, such as an enterprise network or the Internet. Such networks may be based on any suitable technology and may operate according to any suitable protocol and may include wireless networks, wired networks or fiber optic networks.

Also, the various methods or processes outlined herein may be coded as software that is executable on one or more processors that employ any one of a variety of operating systems or platforms. Additionally, such software may be written using any of a number of suitable programming languages and/or programming or scripting tools, and also may be compiled as executable machine language code or intermediate code that is executed on a framework or virtual machine.

In this respect, the invention may be embodied as a computer readable storage medium (or multiple computer readable media) (e.g., a computer memory, one or more floppy discs, compact discs (CD), optical discs, digital video disks (DVD), magnetic tapes, flash memories, circuit configurations in Field Programmable Gate Arrays or other semiconductor devices, or other tangible computer storage medium) encoded with one or more programs that, when executed on one or more computers or other processors, perform methods that implement the various embodiments of the invention discussed above. As is apparent from the foregoing examples, a computer readable storage medium may retain information for a sufficient time to provide computer-executable instructions in a non-transitory form. Such a computer readable storage medium or media can be transportable, such that the program or programs stored thereon can be loaded onto one or more different computers or other processors to implement various aspects of the present invention as discussed above. As used herein, the term “computer-readable storage medium” encompasses only a computer-readable medium that can be considered to be a manufacture (i.e., article of manufacture) or a machine. Alternatively or additionally, the invention may be embodied as a computer readable medium other than a computer-readable storage medium, such as a propagating signal.

The terms “program” or “software” are used herein in a generic sense to refer to any type of computer code or set of computer-executable instructions that can be employed to program a computer or other processor to implement various aspects of the present invention as discussed above. Additionally, it should be appreciated that according to one aspect of this embodiment, one or more computer programs that when executed perform methods of the present invention need not reside on a single computer or processor, but may be distributed in a modular fashion amongst a number of different computers or processors to implement various aspects of the present invention.

Computer-executable instructions may be in many forms, such as program modules, executed by one or more computers or other devices. Generally, program modules include routines, programs, objects, components, data structures, etc. that perform particular tasks or implement particular abstract data types. Typically the functionality of the program modules may be combined or distributed as desired in various embodiments.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that conveys relationship between the fields. However, any suitable mechanism may be used to establish a relationship between information in fields of a data structure, including through the use of pointers, tags or other mechanisms that establish relationship between data elements.

Various aspects of the present invention may be used alone, in combination, or in a variety of arrangements not specifically discussed in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Also, the invention may be embodied as a method, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

1. A printed circuit board comprising:
an insulating portion;
a plurality of conductive traces disposed in a plurality of planes, the plurality of conductive traces being supported by the insulating portion; and
conductive vias electrically interconnecting predetermined conductive traces of the plurality of conductive traces, wherein the conductive traces connect to respective conductive vias in breakout regions and wherein at least one parameter of a breakout region is configured to provide a desired electrical characteristic.

2. A printed circuit board as defined in claim 1, wherein the at least one parameter of the breakout region is configured to provide a desired impedance profile in the breakout region.

3. A printed circuit board as defined in claim 1, wherein the at least one parameter of the breakout region is configured to limit impedance discontinuities in the breakout region.

4. A printed circuit board as defined in claim 1, wherein breakout trace portions in the breakout region have a different width and/or thickness than trace portions outside the breakout region.

5. A printed circuit board as defined in claim 1, wherein breakout trace portions are configured to match an impedance of a connected via.

6. A printed circuit board as defined in claim 1, wherein breakout trace portions in breakout region are configured to match an impedance of trace portions outside the breakout region.

7. A printed circuit board as defined in claim 1, wherein:
the at least one parameter comprises trace width; and
breakout trace portions have different widths based on proximity to a ground plane and/or anti-pad.

8. A printed circuit board as defined in claim 1, wherein:
the conductive vias comprise backdrilled vias and non-back drilled vias; and
breakout regions connected to the backdrilled vias have different values of the at least one parameter than breakout regions connected to the non-back drilled vias.

9. A printed circuit board as defined in claim 1, wherein:
the conductive traces comprise a pair of traces passing through the same breakout region, and the at least one parameter comprises a spacing between the traces of the pair.

10. A printed circuit board as defined in claim 1, wherein:
the conductive traces comprise a pair of traces passing through the same breakout region and the traces of the pair jog towards each other within the same breakout region.

11. A printed circuit board as defined in claim 1, wherein:
the conductive traces change width over the breakout region.

12. A printed circuit board as defined in claim 1, wherein:
the at least one parameter comprises an angle at which a breakout trace portion exits a connected via.

13. A printed circuit board as defined in claim 1, wherein:
the breakout region includes an anti-pad; and
the at least one parameter comprises a length of a breakout trace portion over the anti-pad.

14. A printed circuit board as defined in claim 1, wherein:
the breakout region includes an anti-pad; and
the at least one parameter comprises a size of the anti-pad.

15. A printed circuit board as defined in any of claims claim 1, wherein:
the at least one parameter comprises a direction of exit of a breakout trace portion from the breakout region.

16. A printed circuit board as defined in claim 1, wherein:
the breakout region includes an anti-pad in a ground plane; and
the at least one parameter comprises a width of a breakout trace portion over the anti-pad, the width being greater over the anti-pad than a width of the trace over the ground plane.

17. A method of fabricating a printed circuit board, comprising:
configuring, by a computing system, electrical interconnections of a printed circuit board, the printed circuit board including at least one insulating sheet, conductive vias between different layers of the printed circuit board, and conductive traces connected to the vias, wherein the conductive traces connect to respective vias in breakout regions;
selecting, by the computing system, at least one parameter of a breakout region to provide a desired electrical characteristic;
patterning conductive structures on the at least one insulating sheet to provide the configured electrical interconnections; and
forming the at least one insulating sheet into the printed circuit board.

18. A method of fabricating a printed circuit board as defined in claim 17, wherein selecting at least one parameter comprises selecting the parameter to provide a desired impedance profile in the breakout region.

19. A method of fabricating a printed circuit board as defined in claim 17, wherein selecting at least one parameter comprises selecting the at least one parameter to limit impedance discontinuities in the breakout region.

20. A method of fabricating a printed circuit board as defined in claim 17, wherein selecting at least one parameter comprises configuring breakout trace portions to match an impedance of a connected via.

21. A method of fabricating a printed circuit board as defined in claim 17, wherein selecting at least one parameter comprises configuring breakout trace portions to match an impedance of a connected trace.

22. A method of fabricating a printed circuit board as defined in claim 17, wherein selecting at least one parameter comprises selecting a width and/or a thickness of a breakout trace portion.

23. A method of fabricating a printed circuited board as defined in claim 17, wherein selecting at least one parameter comprises selecting an angle at which a breakout trace portion exits a connected via.

24. A method of fabricating a printed circuit board as defined in claim 17, wherein selecting at least one parameter comprises selecting a spacing between breakout trace portions in the breakout region.

25. A method of fabricating a printed circuit board as defined in claim 17, wherein the breakout region includes an anti-pad and wherein selecting at least one parameter comprises selecting a length of a breakout trace portion over the anti-pad.

26. A method of fabricating a printed circuit board as defined in claim 17, wherein the breakout region includes an anti-pad and wherein selecting at least one parameter comprises selecting a size of the anti-pad.

27. A method of fabricating a printed circuit board as defined in claim 17, wherein selecting at least one parameter comprises selecting a direction of exit of a breakout trace portion from the breakout region.

28. A method of fabricating a printed circuit board as defined in claim 17, wherein selecting at least one parameter comprises compensating for a discontinuity in a ground plane so as to limit impedance discontinuities in the breakout region.

29. (canceled)

30. A computer-readable storage device encoded with computer-executable instructions that, when executed by a computing device, perform a method of designing a printed circuit board, comprising:
configuring electrical interconnections of the printed circuit board, the printed circuit including at least one insulating sheet, conductive vias between different layers of the printed circuit board and conductive traces connected to respective vias, wherein the conductive traces connect to respective vias in breakout regions; and
selecting at least one parameter of a breakout region to provide a desired electrical characteristic.
